(19) United States
(12) Patent Application Publication
(10) Pub. No.: US 2024/0321980 A1
(43) Pub. Date: Sep. 26, 2024

(54) INTEGRATED CIRCUIT DEVICE AND METHOD OF MANUFACTURING THE SAME

(71) Applicant: SAMSUNG ELECTRONICS CO., LTD., Suwon-si (KR)

(72) Inventors: Doohyun LEE, Suwon-si (KR); Heonjong SHIN, Suwon-si (KR); Jaehyun KANG, Suwon-si (KR); Seonbae KIM, Suwon-si (KR); Wangseop LIM, Suwon-si (KR); Seunghyun HWANG, Suwon-si (KR)

(21) Appl. No.: 18/596,772

(22) Filed: Mar. 6, 2024

(30) Foreign Application Priority Data
Mar. 24, 2023 (KR) 10-2023-0038965
Jun. 14, 2023 (KR) 10-2023-0076421

(51) Int. Cl. H01L 29/417; H01L 29/06; H01L 29/08; H01L 29/40; H01L 29/423; H01L 29/66; H01L 29/775

(52) U.S. Cl. CPC H01L 29/41733; H01L 29/0673; H01L 29/0847; H01L 29/401; H01L 29/42392; H01L 29/66439; H01L 29/775

(57) ABSTRACT

An integrated circuit device includes a substrate having a main surface and fin-type active regions protruding in a vertical direction from the main surface and extending lengthwise in a first horizontal direction, gate lines extending parallel to one another in a second horizontal direction perpendicular to the first horizontal direction and crossing the fin-type active regions, source/drain regions on the fin-type active regions between the gate lines, an inter-gate insulation layer covering the source/drain regions between the gate lines, active contacts on and in contact with the source/drain regions, and a buried insulation block between adjacent ones of the source/drain regions in the second horizontal direction, the buried insulation block penetrating through at least a portion of the inter-gate insulation layer and having a top surface in contact with a first active contact of the active contacts.

### CROSS-REFERENCE TO RELATED APPLICATIONS

This application is based on and claims priority under 35 U.S.C. § 119 to Korean Patent Application Nos. 10-2023-0038965, filed on Mar. 24, 2023, and 10-2023-0076421, filed on Jun. 14, 2023, in the Korean Intellectual Property Office, the disclosures of which are incorporated by reference herein in their entirety.

### BACKGROUND

### 1. Field

Embodiments relate to an integrated circuit device, and more particularly, to an integrated circuit device including a field-effect transistor.

### 2. Description of the Related Art

Recently, as down-scaling of integrated circuit devices proceeds rapidly, it is desired to secure not only a fast operation speed but also operation accuracy in an integrated circuit device. Therefore, various studies are being conducted to provide an integrated circuit device having a structure capable of providing optimal performance and improved reliability.

### SUMMARY

According to embodiments, there is provided an integrated circuit device. The integrated circuit device includes a substrate having a main surface and having a plurality of fin-type active regions protruding in a vertical direction from the main surface and long in a first horizontal direction, a plurality of gate lines extending parallel to one another in a second horizontal direction perpendicular to the first horizontal direction and crossing the plurality of fin-type active regions on the substrate, a plurality of source/drain regions arranged on the plurality of fin-type active regions between the plurality of gate lines, an inter-gate insulation layer covering the plurality of source/drain regions between the plurality of gate lines, a plurality of active contacts arranged on the plurality of source/drain regions and in contact with the plurality of source/drain regions, and a buried insulation block disposed between a first source/drain region selected from among the plurality of source/drain regions and a second source/drain region, which is selected from among the plurality of source/drain regions and is adjacent to the first source/drain region in the second horizontal direction, penetrating through at least a portion of the inter-gate insulation layer, and having a top surface in contact with a first active contact selected from among the plurality of active contacts.

According to embodiments, there is provided an integrated circuit device. The integrated circuit device includes a substrate having a main surface and having a plurality of fin-type active regions protruding in a vertical direction from the main surface and long in a first horizontal direction, a plurality of gate lines extending parallel to one another in a second horizontal direction perpendicular to the first horizontal direction and crossing the plurality of fin-type active regions on the substrate, a plurality of source/drain regions arranged on the plurality of fin-type active regions between the plurality of gate lines and each including a lower portion having a width in the second horizontal direction increasing as a distance from the main surface of the substrate in the vertical direction increases and an upper portion having a width in the second horizontal direction decreasing as a distance from the main surface of the substrate in the vertical direction increases, an inter-gate insulation layer covering the plurality of source/drain regions between the plurality of gate lines, a buried insulation block disposed between a first source/drain region selected from among the plurality of source/drain regions and a second source/drain region, which is selected from among the plurality of source/drain regions and is adjacent to the first source/drain region in the second horizontal direction, penetrating through at least a portion of the inter-gate insulation layer, and extending in the vertical direction, and an active contact including a first portion in contact with a top surface of the first source/drain region and a top surface of the second source/drain region and a second portion, which protrudes from the first portion toward the substrate in the vertical direction and contacts a top surface of the buried insulation block.

According to embodiments, there is provided an integrated circuit device. The integrated circuit device includes a substrate having a plurality of fin-type active regions that are long in a first horizontal direction, a plurality of gate lines extending parallel to one another in a second horizontal direction perpendicular to the first horizontal direction and crossing the plurality of fin-type active regions on the substrate, a plurality of source/drain pairs arranged on the plurality of fin-type active regions between the plurality of gate lines and each including two source/drain regions adjacent to each other in the second horizontal direction, an insulation liner covering the plurality of source/drain pairs between the plurality of gate lines, an inter-gate insulation layer on the insulation liner, a plurality of buried insulation blocks arranged between the plurality of source/drain pairs, a plurality of active contacts arranged on the plurality of source/drain pairs and in contact with the plurality of buried insulation blocks, respectively, and a plurality of contact cut insulation portions extending in a vertical direction between the plurality of gate lines on the substrate and arranged between the plurality of active contacts in the second horizontal direction, respectively.

### BRIEF DESCRIPTION OF THE DRAWINGS

Features will become apparent to those of skill in the art by describing in detail exemplary embodiments with reference to the attached drawings, in which:

FIG. 1 is a schematic plan layout diagram of some components of an integrated circuit device according to embodiments;

FIG. 2A is a cross-sectional view of some components, taken along line X1-X1′ of FIG. 1;

FIG. 2B is a cross-sectional view of some components, taken along line X2-X2′ of FIG. 1;

FIG. 2C is a cross-sectional view of some components, taken along line Y1-Y1′ of FIG. 1;

FIG. 2D is an enlarged view of region EX1 in FIG. 2C;

FIGS. 3A to 3E are cross-sectional views of integrated circuit devices according to other embodiments corresponding to region EX1 in FIG. 2C; and

FIGS. 4A to 8B are cross-sectional views of stages in a method of manufacturing an integrated circuit device according to embodiments, wherein FIGS. 4A, 5A, 6A, 7A, and 8A are cross-sectional views of some components corresponding to the cross-section along line X2-X2′ of FIG. 1, and FIGS. 4B, 5B, 6B, 7B, and 8B are cross-sectional views of some components corresponding to the cross-section along line Y1-Y1′ of FIG. 1.

### DETAILED DESCRIPTION

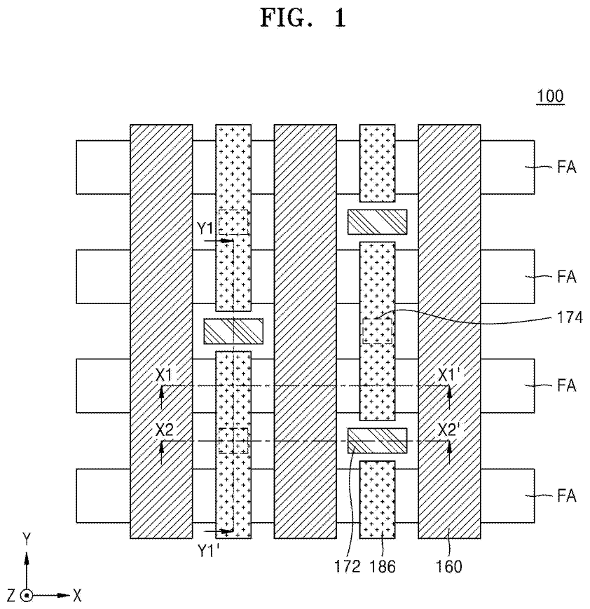

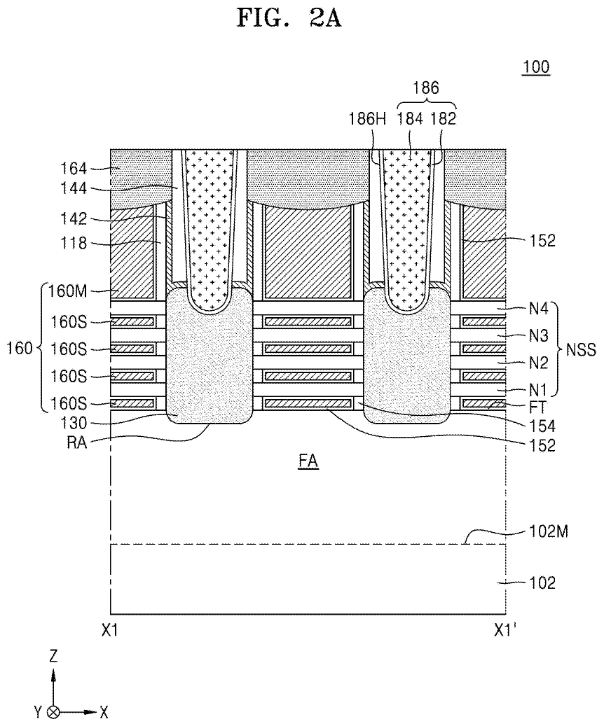

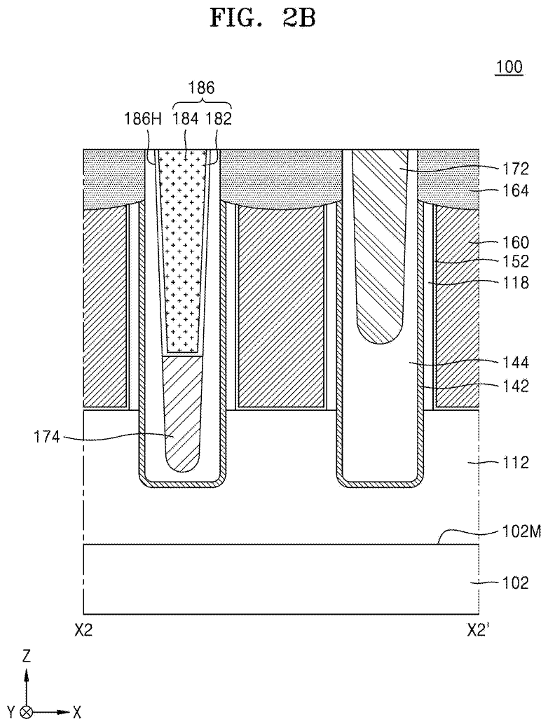

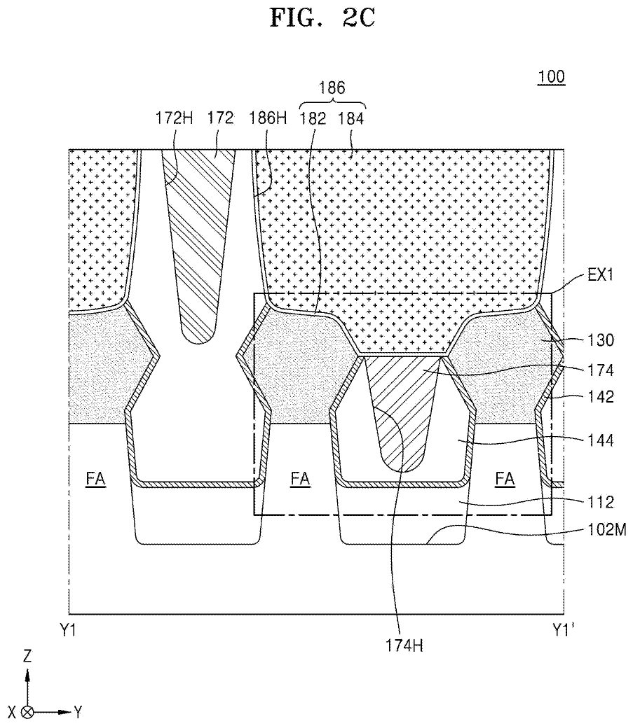

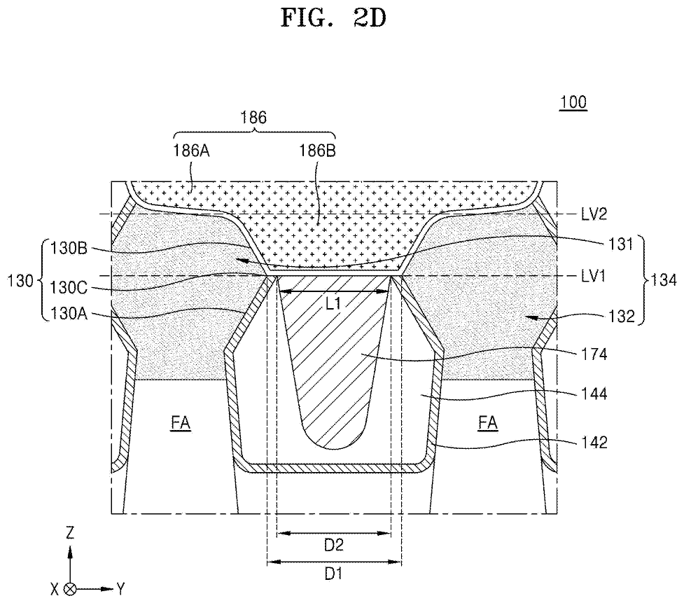

FIG. 1 is a schematic plan layout diagram of some components of an integrated circuit device 100 according to embodiments. FIG. 2A is a cross-sectional view of some components, taken along line X1-X1′ of FIG. 1. FIG. 2B is a cross-sectional view of some components, taken along line X2-X2′ of FIG. 1. FIG. 2C is a cross-sectional view of some components, taken along line Y1-Y1′ of FIG. 1. FIG. 2D is an enlarged view of region EX1 in FIG. 2C.

According to embodiments described below with reference to FIGS. 1 and 2A to 2D, the integrated circuit device 100 may constitute a logic cell including a gate-all-around type field-effect transistor (FET) device including a nano-wire or a nano-sheet type active region and a gate surrounding the active region. For example, the integrated circuit device 100 may include a multi-bridge channel FET (MBCFET) device. In another example, the integrated circuit device 100 may include a planar FET device, a finFET device, etc.

Referring to FIGS. 1 and 2A to 2D, the integrated circuit device 100 may include a substrate 102 having a plurality of fin-type active regions FA. The plurality of fin-type active regions FA may protrude in a vertical direction (Z direction) from a main surface 102M of the substrate 102. The plurality of fin-type active regions FA may extend parallel to each other in a first horizontal direction (X direction) and may be spaced apart from each other in a second horizontal direction (Y direction) intersecting with the first horizontal direction (X direction).

According to some embodiments, the substrate 102 may include a semiconductor material, e.g., Si or Ge, or a compound semiconductor material, e.g., SiGe, SiC, GaAs, InAs, InGaAs, or InP. The terms SiGe, SiC, GaAs, InAs, InGaAs, and InP as used herein refer to a material composed of elements included in each term and is not a formula representing a stoichiometric relationship. The substrate 102 may include a conductive region, e.g., a well doped with an impurity or a structure doped with an impurity.

A device isolation layer 112 covering lower portions of both sidewalls of each of the plurality of fin-type active regions FA may be disposed on the substrate 102. The device isolation layer 112 may include, e.g., an oxide film, a nitride film, or a combination thereof.

According to embodiments, on the plurality of fin-type active regions FA and the device isolation layer 112, a plurality of gate lines 160 that are spaced apart from each other in the first horizontal direction (X direction) and extend in parallel with each other in the second horizontal direction (Y direction) may be arranged. In regions where the plurality of fin-type active regions FA and the plurality of gate lines 160 intersect with each other, the plurality of nano-sheet stacks NSS may be arranged over fin top surfaces FT of the plurality of fin-type active regions FA, respectively. The plurality of nano-sheet stacks NSS may face the fin top surfaces FT at positions spaced apart from the plurality of fin-type active regions FA in the vertical direction (Z direction). The term “nano-sheet” as used herein refers to a conductive structure having a cross-section substantially perpendicular to a direction in which an electric current flows. It should be understood that a nano-sheet includes nano-wires.

According to embodiments, the plurality of nano-sheet stacks NSS may include a first nano-sheet N1, a second nano-sheet N2, a third nano-sheet N3, and a fourth nano-sheet N4 overlapping one another in the vertical direction (Z direction) over a fin top surface FT of the fin-type active region FA. According to some embodiments, vertical distances from the fin top surface FT to the first nano-sheet N1, the second nano-sheet N2, the third nano-sheet N3, and the fourth nano-sheet N4 may be different from one another. For example, any suitable number of nano-sheet stacks NSS and gate lines 160 arranged on the fin top surface FT of the fin-type active region FA may be implemented. For example, one or a plurality of nano-sheet stacks NSS and one or a plurality of gate lines 160 may be arranged on one fin-type active region FA.

For example, as illustrated in FIG. 2A, each of the plurality of nano-sheet stacks NSS may include the first nano-sheet N1, the second nano-sheet N2, the third nano-sheet N3, and the fourth nano-sheet N4. Any suitable number of nano-sheets may be implemented to constitute one nano-sheet stack NSS, e.g., each of the plurality of nano-sheet stacks NSS may include one or more nano-sheets. The first nano-sheet N1, the second nano-sheet N2, the third nano-sheet N3, and the fourth nano-sheet N4 may each have a channel region. According to some embodiments, the first nano-sheet N1, the second nano-sheet N2, the third nano-sheet N3, and the fourth nano-sheet N4 may have substantially the same thicknesses in the vertical direction (Z direction). According to some other embodiments, at least some of the first nano-sheet N1, the second nano-sheet N2, and the third nano-sheet N3 may have different thicknesses in the vertical direction (Z direction).

According to some embodiments, the first nano-sheet N1, the second nano-sheet N2, the third nano-sheet N3, and the fourth nano-sheet N4 included in one nano-sheet stack NSS may have the same size as one another in the first horizontal direction (X direction). According to some other embodiments, at least some of the first nano-sheet N1, the second nano-sheet N2, the third nano-sheet N3, and the fourth nano-sheet N4 included in one nano-sheet stack NSS may have different sizes in the first horizontal direction (X direction). For example, from among the first nano-sheet N1, the second nano-sheet N2, the third nano-sheet N3, and the fourth nano-sheet N4, the length of each of the first nano-sheet N1 and the second nano-sheet N2, which are relatively close to the fin top surface FT, in the first horizontal direction (X direction) may be greater than the length of each of the third nano-sheet N3 and the fourth nano-sheet N4, which are relatively far from the fin top surface FT, in the first horizontal direction (X direction).

According to embodiments, a plurality of recesses RA may be formed in the plurality of fin-type active regions FA, respectively. For example, as illustrated in FIG. 2A, the level of the lowermost surfaces of the plurality of recesses RA is lower than the level of the fin top surfaces FT of the plurality of fin-type active regions FA. For example, the level of the lowermost surfaces of the plurality of recesses RA may be the same as or similar to the level of the fin top surface FT of the plurality of fin-type active region FAs. A plurality of source/drain regions 130 may be arranged over, e.g., in, the plurality of recesses RA. According to embodiments, the plurality of source/drain regions 130 may be arranged between a plurality of nano-sheet stacks NSS over the plurality of fin-type active regions FA. For example, the plurality of source/drain regions 130 may be arranged between two nano-sheet stacks NSS adjacent to each other in the first horizontal direction (X direction).

According to embodiments, the plurality of gate lines 160 may cover the plurality of nano-sheet stacks NSS over the plurality of fin-type active regions FA and surround the first nano-sheet N1, the second nano-sheet N2, the third nano-sheet N3, and the fourth nano-sheet N4 included in each of the plurality of nano-sheet stacks NSS. A plurality of transistors may be formed in portions on the substrate 102 where the plurality of fin active regions FA and the plurality of gate lines 160 intersect with each other. According to embodiments, at least some of the plurality of transistors may be NMOS transistor regions. According to other embodiments, at least some of the plurality of transistors may be PMOS transistor regions.

As shown in FIGS. 2A and 2B, the plurality of gate lines 160 may each include a main gate portion 160M and a plurality of sub-gate portions 160S. The main gate portion 160M may cover the top surface of the nano-sheet stack NSS and extend long (e.g., lengthwise) in the second horizontal direction (Y direction). The plurality of sub-gate portions 160S may be integrally connected to the main gate portion 160M and may be disposed between the first nano-sheet N1, the second nano-sheet N2, the third nano-sheet N3, and the fourth nano-sheet N4 and between the fin top surface FT of the fin-type active region FA and the first nano-sheet N1.

According to some embodiments, the plurality of gate lines 160 may each include, e.g., a metal, a metal nitride, a metal carbide, or a combination thereof. The metal may be selected from, e.g., Ti, W, Ru, Nb, Mo, Hf, Ni, Co, Pt, Yb, Tb, Dy, Er, and Pd. The metal nitride may be selected from, e.g., TiN and TaN. The metal carbide may be, e.g., TiAlC. According to embodiments, the plurality of gate lines 160 may each have a structure in which a metal nitride layer, a metal layer, a conductive capping layer, and a gap-fill metal layer are sequentially stacked. The metal nitride layer and the metal layer may include at least one metal selected from, e.g., Ti, Ta, W, Ru, Nb, Mo, and Hf. The gap-fill metal layer may include, e.g., W, Al, or a combination thereof.

According to embodiments, a gate dielectric layer 152 may be provided between the first nano-sheet N1, the second nano-sheet N2, the third nano-sheet N3, and the fourth nano-sheet N4 of each of the plurality of nano-sheet stacks NSS and the gate line 160. The gate dielectric layer 152 may include portions respectively covering surfaces of the first nano-sheet N1, second nano-sheet N2, third nano-sheet N3, and fourth nano-sheet N4 and portions covering sidewalls of the main gate portion 160M.

According to embodiments, the gate dielectric layer 152 may include a stacked structure of an interfacial layer and a high-k layer. The interfacial layer may include a low-k material layer having a dielectric constant of about 9 or less, e.g., a silicon oxide layer, a silicon oxynitride layer, or a combination thereof. According to embodiments, the interfacial layer may be omitted. The high-k layer may include a material having a higher dielectric constant than that of a silicon oxide layer. For example, the high-k layer may have a dielectric constant from about 10 to about 25. The high-k layer may include, e.g., hafnium oxide.

According to embodiments, at least some of the plurality of source/drain regions 130 may each include a Si layer doped with an n-type dopant or a SiC layer doped with an n-type dopant. The n-type dopant may be selected from, e.g., phosphorus(P), arsenic (As), and antimony (Sb). According to other embodiments, at least some of the plurality of source/drain regions 130 may each include a SiGe layer doped with a p-type dopant. The p-type dopant may be selected from, e.g., boron(B) and gallium (Ga). The plurality of source/drain regions 130 may each have various shapes and sizes according to the channel type of the transistor.

In each of the plurality of nano-sheet stacks NSS, the first nano-sheet N1, the second nano-sheet N2, the third nano-sheet N3, and the fourth nano-sheet N4 may include semiconductor layers containing the same element. For example, the first nano-sheet N1, the second nano-sheet N2, the third nano-sheet N3, and the fourth nano-sheet N4 may each include a Si layer.

The plurality of nano-sheet stacks NSS may each contact the source/drain regions 130 adjacent thereto in the first horizontal direction (X direction). According to embodiments, the first nano-sheet N1, the second nano-sheet N2, the third nano-sheet N3, and the fourth nano-sheet N4 may be doped with a dopant of the same conductivity type as the source/drain regions 130 contacting them. According to some embodiments, the first nano-sheet N1, the second nano-sheet N2, the third nano-sheet N3, and the fourth nano-sheet N4 may each include a Si layer doped with an n-type dopant. According to some other embodiments, the first nano-sheet N1, the second nano-sheet N2, the third nano-sheet N3, and the fourth nano-sheet N4 may each include a Si layer doped with a p-type dopant.

As shown in FIGS. 2A and 2B, both sidewalls of each of the plurality of gate lines 160 in the first horizontal direction (X direction) may be covered by a plurality of outer insulation spacers 118. The plurality of outer insulation spacers 118 may each include a portion covering both sidewalls of the main gate portion 160M over the top surface of the nano-sheet stack NSS and a portion covering the gate line 160 over the device isolation layer 112, respectively. The plurality of outer insulation spacers 118 may each be spaced apart from the gate line 160 with the gate dielectric layer 152 therebetween.

According to embodiments, the plurality of outer insulation spacers 118 may each include, e.g., silicon nitride, silicon oxide, SiOC, SiOCN, SiCN, SiBN, SiON, SiBCN, SiOF, SiOCH, or a combination thereof. The plurality of outer insulation spacers 118 may each include a single layer containing one material selected from among the above-stated materials or a multi-layer including a plurality of materials selected from among the above-stated materials. The terms SiOC, SiOCN, SiCN, SiBN, SION, SiBCN, SiOF, and SiOCH as used herein refer to a material composed of elements included in each term and is not a formula representing a stoichiometric relationship.

As shown in FIG. 2A, a plurality of inner insulation spacers 154 may be arranged between the first nano-sheet N1, the second nano-sheet N2, the third nano-sheet N3, and the fourth nano-sheet N4 and between the fin top surface FT of the fin-type active region FA and the first nano-sheet N1. According to embodiments, in the first horizontal direction (X direction), both sidewalls of each of the plurality of sub-gate portions 160S may be covered by the inner insulation spacers 154 with the gate dielectric layer 152 therebetween. The plurality of sub-gate portions 160S may be spaced apart from the source/drain region 130 with the gate dielectric layer 152 and the inner insulation spacer 154 therebetween. At least some of the plurality of inner insulation spacers 154 may overlap the outer insulation spacers 118 in the vertical direction (Z direction).

The plurality of source/drain regions 130 may contact the plurality of inner insulation spacers 154 adjacent thereto in the first horizontal direction (X direction), respectively. The plurality of inner insulation spacers 154 may each include a first sidewall facing the sub-gate portion 160S of the gate line 160 and a second sidewall facing the source/drain region 130 adjacent thereto. The plurality of source/drain regions 130 may include portions contacting the plurality of inner insulation spacers 154 adjacent thereto.

According to some embodiments, the plurality of inner insulation spacers 154 may each include, e.g., silicon nitride, silicon oxide, SiOC, SiOCN, SiCN, SiBN, SION, SiBCN, SiOF, SiOCH, or a combination thereof. The plurality of inner insulation spacers 154 may each include a single layer containing one material selected from among the above-stated materials or a multi-layer including a plurality of materials selected from among the above-stated materials.

According to embodiments, the outer insulation spacer 118 and the inner insulation spacer 154 may include the same material. According to other embodiments, the outer insulation spacer 118 and the inner insulation spacer 154 may include different materials.

As shown in FIG. 2A, the main gate portion 160M of the gate line 160 may be spaced apart from the source/drain region 130 with the outer insulation spacer 118 therebetween.

As shown in FIGS. 2A and 2C, the plurality of source/drain regions 130 may be covered by an insulation liner 142. According to embodiments, the insulation liner 142 may conformally cover surfaces of the plurality of source/drain regions 130, the outer insulation spacer 118, the top surface of the device isolation layer 112, and sidewalls of the upper portions of the plurality of fin-type active regions FA. For example, the insulation liner 142 may cover the plurality of source/drain regions 130 between the plurality of gate lines 160.

According to embodiments, the insulation liner 142 may be covered by an inter-gate insulation layer 144. The inter-gate insulation layer 144 may be disposed between the plurality of gate lines 160 extending parallel to each other in the second horizontal direction (Y direction). According to embodiments, the inter-gate insulation layer 144 may cover the plurality of source/drain regions 130 over the insulation liner 142. For example, the plurality of source/drain regions 130 may face the inter-gate insulation layer 144 with the insulation liner 142 therebetween.

As shown in FIGS. 2A and 2B, top surfaces of the gate line 160, the gate dielectric layer 152, and the insulation liner 142 may be covered by a capping insulation layer 164. According to some embodiments, the capping insulation layer 164 may include, e.g., a silicon nitride film or a SiCN film. According to some embodiments, the insulation liner 142 may include, e.g., a silicon nitride film, a SiCN film, a SiBN film, a SiON film, a SiOCN film, a SiBCN film, a SiOC film, a silicon oxide film, or a combination thereof. According to some embodiments, the inter-gate insulation layer 144 may include, e.g., a silicon oxide layer, a silicon nitride layer, a SiON layer, a SiOCN layer, or a combination thereof.

According to some embodiments, the insulation liner 142 and the inter-gate insulation layer 144 may include different materials. For example, the insulation liner 142 and the inter-gate insulation layer 144 may have different etch selectivity.

Unlike those shown in FIGS. 2A and 2B, the capping insulation layer 164 may cover the top surfaces of the gate line 160 and the gate dielectric layer 152 but may not cover the top surface of the insulation liner 142. For example, sidewalls of the capping insulation layer 164 may contact the insulation liner 142 and, in this case, may face the inter-gate insulation layer with the insulation liner 142 therebetween. According to some embodiments, the insulation liner 142 and the capping insulation layer 164 may include the same material.

As shown in FIGS. 2A and 2C, a plurality of active contacts 186 may be arranged on the plurality of source/drain regions 130. The plurality of active contacts 186 may each fill a contact hole 186H penetrating through the inter-gate insulation layer 144, the insulation liner 142, and some of the plurality of source/drain regions 130 in the vertical direction (Z direction). For example, some of the plurality of active contacts 186 may extend into the plurality of source/drain regions 130 in the vertical direction (Z direction). The plurality of active contacts 186 may each contact two source/drain regions 130 adjacent to each other in the second horizontal direction (Y direction) from among the plurality of source/drain regions 130, e.g., a single active contact 186 may directly contact two adjacent source/drain regions 130 (FIG. 2C).

According to embodiments, the plurality of source/drain regions 130 may include a plurality of source/drain pairs 134 each including two source/drain regions 130 adjacent to each other in the second horizontal direction (Y direction). For example, each source/drain pair 134 may include a first source/drain region 131 and a second source/drain region 132 (FIG. 2D). The plurality of active contacts 186 may be individually connected to the plurality of source/drain pairs 134, respectively. For example, the plurality of active contacts 186 may each contact the first source/drain region 131 and the second source/drain region 132.

According to some embodiments, the plurality of active contacts 186 may contact surfaces of the plurality of source/drain regions 130, respectively. For example, the top surfaces of the plurality of source/drain regions 130 may contact the plurality of active contacts 186, respectively. In this case, the top surfaces of the plurality of source/drain regions 130 refer to the top surfaces of portions of the plurality of source/drain regions 130 vertically overlapping the plurality of active contacts 186.

According to embodiments, the plurality of active contacts 186 may each include a conductive barrier 182 that partially fills the contact hole 186H and, e.g., continuously, covers the inner wall and the bottom of the contact hole 186H and a conductive plug 184 that fills the remaining portion of the contact hole 186H and is disposed on the conductive barrier 182. The conductive barrier 182 may contact the plurality of source/drain regions 130 and may be disposed between the conductive plug 184 and the plurality of source/drain regions 130.

According to some embodiments, the conductive barrier 182 may include, e.g., Ti, Ta, W, TiN, TaN, WN, WCN, TiSiN, TaSiN, WSiN, or a combination thereof. According to some embodiments, the conductive plug 184 may include, e.g., Mo, Cu, W, Co, Ru, Mn, Ti, Ta, Al, a combination thereof, or an alloy thereof.

For example, a metal silicide may be disposed between the plurality of active contacts 186 and the plurality of source/drain regions 130. For example, the plurality of active contacts 186 may contact the metal silicide while covering the plurality of source/drain regions 130. For example, the metal silicide may include, e.g., Ti, W, Ru, Nb, Mo, Hf, Ni, Co, Pt, Yb, Tb, Dy, Er, or Pd. According to some other embodiments, the metal silicide may be omitted between the plurality of active contacts 186 and the plurality of source/drain regions 130, and, in this case, the plurality of active contacts 186 and the plurality of source/drain regions 130 may directly contact each other. Therefore, in this specification, the expression “the plurality of active contacts 186 cover the plurality of source/drain regions 130” may be interpreted as that “the plurality of active contacts 186 contact the plurality of source/drain regions 130”.

As shown in FIGS. 1, 2A, and 2B, the plurality of active contacts 186 may be arranged between the plurality of gate lines 160 extending parallel to each other in the second horizontal direction (Y direction). For example, two active contacts 186 selected from among the plurality of active contacts 186 and adjacent to each other in the first horizontal direction (X direction) may be spaced apart from each other with the gate line 160 therebetween.

According to embodiments, a plurality of contact cut insulation portions 172 may each be disposed between the plurality of active contacts 186 in the second horizontal direction (Y direction). As shown in FIGS. 1 and 2C, on some of regions between the plurality of fin-type active regions FA, the plurality of contact cut insulation portions 172 penetrate through at least a portion of the inter-gate insulation layer 144 in the vertical direction (Z direction) and may extend into the inter-gate insulation layer 144.

For example, as illustrated in FIGS. 2B and 2C, the plurality of contact cut insulation portions 172 are arranged within the inter-gate insulation layer 144. For example, unlike those shown in FIGS. 2B and 2C, the plurality of contact cut insulation portions 172 may extend more deeply in the vertical direction (Z direction) to penetrate through the inter-gate insulation layer 144 and contact the insulation liner 142.

According to some embodiments, the plurality of contact cut insulation portions 172 may each have a tapered shape such that the width of each of the plurality of contact cut insulation portions 172 in the second horizontal direction (Y direction) decreases in a direction oriented away from the top surface of each of the plurality of contact cut insulation portions 172 in the vertical direction (Z direction). For example, the horizontal width of a portion of each of the plurality of contact cut insulation portions 172 relatively close to the main surface 102M of the substrate 102 may be less than the horizontal width of a portion of each of the plurality of contact cut insulation portions 172 relatively far from the main surface 102M of the substrate 102.

According to some embodiments, the inter-gate insulation layer 144 may be disposed between the plurality of contact cut insulation portions 172 and the plurality of active contacts 186 in the second horizontal direction (Y direction). For example, the plurality of contact cut insulation portions 172 may be formed by forming contact cut holes 172H in the inter-gate insulation layer 144 and filling the contact cut holes 172H with an insulation material, and the plurality of active contacts 186 may be formed by forming contact holes 186H by removing portions of the inter-gate insulation layer 144 by using the plurality of contact cut insulation portions 172 as an etch mask and filling the contact holes 186H with a conductive material. Thereafter, a planarization process may be performed, and the plurality of contact cut insulation portions 172 may be spaced apart from the plurality of active contacts 186 in the second horizontal direction (Y direction) with the inter-gate insulation layer 144 therebetween. According to some embodiments, the top surface of the capping insulation layer 164, the top surface of the inter-gate insulation layer 144, the top surfaces of the plurality of contact cut insulation portions 172, and the top surfaces of the plurality of active contacts 186 may be coplanar with one another.

According to some other embodiments, if a planarization process is not performed or only upper portions of the plurality of contact cut insulation portions 172 are removed through a planarization process, both sidewalls of the plurality of contact cut insulation portions 172 in the second horizontal direction (Y direction) may contact the active contacts 186 adjacent thereto, respectively.

As shown in FIG. 2B, the plurality of active contacts 186 may face the insulation liner 142 and the capping insulation layer 164 with the inter-gate insulation layer 144 therebetween in the first horizontal direction (X direction). According to some embodiments, in the first horizontal direction (X direction), the plurality of contact cut insulation portions 172 may each face the insulation liner 142 and the capping insulation layer 164 with the inter-gate insulation layer 144 therebetween.

According to some embodiments, the plurality of contact cut insulation portions 172 may include, e.g., a silicon nitride film, a silicon oxide film, a SiCN film, a SiON film, a SiOCN film, or a combination thereof. According to some embodiments, the plurality of contact cut insulation portions 172 may include a material that is different from materials constituting the inter-gate insulation layer 144 and the insulation liner 142.

According to embodiments, a plurality of buried insulation blocks 174 may be arranged under the plurality of active contacts 186, respectively. The plurality of buried insulation blocks 174 may each penetrate through at least a portion of the inter-gate insulation layer 144 and may respectively extend from the plurality of active contacts 186 in the vertical direction (Z direction) toward the substrate 102.

For example, as illustrated in FIGS. 2C and 2D, the plurality of buried insulation blocks 174 may penetrate through a portion of the inter-gate insulation layer 144 and may face the insulation liner 142 with the inter-gate insulation layer 144 therebetween in the vertical direction (Z direction). In another example, the plurality of buried insulation blocks 174 may penetrate through the inter-gate insulation layer 144 in the vertical direction (Z direction) and contact the insulation liner 142. According to some embodiments, the sidewalls and the bottom surfaces of the plurality of buried insulation blocks 174 may be surrounded by the inter-gate insulation layer 144 and the insulation liner 142.

As shown in FIG. 2B, the top surface of each of the plurality of buried insulation blocks 174 may contact (e.g., directly contact) the plurality of active contacts 186 and may face the gate line 160 in the first horizontal direction (X direction) with the inter-gate insulation layer 144, the insulation liner 142, the outer insulation spacer 118, and the gate dielectric layer 152 therebetween. As shown in FIGS. 2C and 2D, the plurality of buried insulation blocks 174 may each be disposed between the source/drain pair 134 (i.e., between the first and second source/drain region 131 and 132 of a same source/drain pair 134), and may be in contact (e.g., direct contact) with the bottom surface of the active contact 186 connected to the same source/drain pair 134. For example, the plurality of buried insulation blocks 174 may each be disposed between the first source/drain region 131 and the second source/drain region 132 in the second horizontal direction (Y direction).

According to embodiments, the plurality of active contacts 186 may each cover one source/drain pair 134 and a buried insulation block 174 between the one source/drain pair 134 together. According to embodiments, the plurality of active contacts 186 may each include a first portion 186A contacting the source/drain pair 134 and a second portion 186B contacting the buried insulation block 174.

According to some embodiments, the second portion 186B may protrude from (e.g., beyond) the bottom surface of the first portion 186A toward the substrate 102 in the vertical direction (Z direction), and may contact the top surface of the buried insulation block 174. The bottom surface of the second portion 186B of each of the plurality of active contacts 186 may be disposed at a lower vertical level than the bottom surface of the first portion 186A of each of the plurality of active contacts 186, e.g., the bottommost surface of the second portion 186B (i.e., a surface in direct contact with the buried insulation block 174) may be at a lower vertical level than the bottom surface of the first portion 186A relative to the bottom of the substrate 102.

As shown in FIGS. 2C and 2D, the plurality of source/drain regions 130 may each have a polygonal shape having a plurality of inclined surfaces. According to some embodiments, the plurality of source/drain regions 130 may each include a first portion 130A having a positive profile (i.e., the width thereof in the second horizontal direction (Y direction) increases in a direction oriented away from the main surface 102M of the substrate 102) and a second portion 130B extending from the first portion 130A in the vertical direction (Z direction) and having a negative profile (i.e., the width thereof in the second horizontal direction (Y direction) decreases in a direction oriented away from the main surface 102M of the substrate 102). For example, sidewalls of the first portion 130A of each of the plurality of source/drain regions 130 may have a positive profile and sidewalls of the second portion 130B of each of the plurality of source/drain regions 130 may have a negative profile. According to some embodiments, the plurality of source/drain regions 130 may include a third portion 130C having a maximum width in the second horizontal direction (Y direction) between the first portion 130A and the second portion 130B, e.g., the third portion 130C may include an apex point between the first and second portions 130A and 130B to define a maximum width of the source/drain regions 130 in the second horizontal direction. According to some embodiments, the third portion 130C may be disposed at a first vertical level LV1. The term “vertical level” as used herein refers to a distance in the vertical direction (Z direction or −Z direction) from the main surface 102M of the substrate 102. In this specification, the first portion 130A of each of the plurality of source/drain regions 130 may be referred to as a lower portion of each of the plurality of source/drain regions 130, and the second portion 130B of each of the plurality of source/drain regions 130 may be referred to as an upper portion of each of the plurality of source/drain regions 130.

According to some embodiments, the first portion 186A of the plurality of active contacts 186 may contact the top surface of the second portion 130B of the source/drain pair 134, and the second portion 186B of each of the plurality of active contacts 186 may contact sidewalls of the second portion 130B of the source/drain pair 134 and the top surfaces of the plurality of buried insulation blocks 174. For example, the second portion 186B of each of the plurality of active contacts 186 may contact the sidewall of the second portion 130B of the first source/drain region 131 and the sidewall of the second portion 130B of the second source/drain region 132 facing each other.

According to some embodiments, the top surfaces of the plurality of buried insulation blocks 174 may be arranged at the first vertical level LV1. The plurality of buried insulation blocks 174 may penetrate through the inter-gate insulation layer 144 and extend to a vertical level lower than the first vertical level LV1. According to some embodiments, the plurality of buried insulation blocks 174 may be arranged between the first portion 130A of the first source/drain region 131 and the first portion 130A of the second source/drain region 132, in the second horizontal direction (Y direction).

According to some embodiments, the second portion 186B of each of the plurality of active contacts 186 may contact the top surface of each of the plurality of buried insulation blocks 174 at the first vertical level LV1. According to some embodiments, first portions 186A of the plurality of active contacts 186 may contact the top surface of the source/drain pair 134 (e.g., the top surface of the second portion 130B of the source/drain pair 134) at a second vertical level LV2 higher than the first vertical level LV1.

For example, as illustrated in FIGS. 2C and 2D, the top surface of the second portion 130B of each of the plurality of source/drain regions 130 has a relatively flat surface and the top surface of the second portion 130B and side surfaces of the second portion 130B in the second horizontal direction (Y direction) meet each other at an angle. For example, the top surface and the side surfaces of the second portions 130B contacting the plurality of active contacts 186 may be recessed to meet each other in a rounded shape in the process of forming the contact hole 186H. For example, the second portions 130B of each of the plurality of source/drain regions 130 may have a top surface having an upwardly convex curved surface, and the top surface of the second portion 130B may contact the first portion 186A and the second portion 186B of the plurality of active contacts 186.

According to some embodiments, the second portion 186B of each of the plurality of active contacts 186 may cover at least portions of the sidewall of the second portion 130B of the first source/drain region 131 and the sidewall of the second portion 130B of the second source/drain region 132 arranged to face each other. According to some embodiments, the second portion 186B of each of the plurality of active contacts 186 may cover the sidewall of the second portion 130B of the source/drain pair 134 but may not cover the sidewall of the first portion 130A of the source/drain pair 134. According to some embodiments, the source/drain pair 134 may contact each of the plurality of active contacts 186 via the top surface of the second portion 130B and via a portion of the sidewall of the second portion 130B.

Referring to FIG. 2D, the first source/drain region 131 and the second source/drain region 132 may be spaced apart from each other by a first separation distance D1 in the second horizontal direction (Y direction). According to some embodiments, the first source/drain region 131 and the second source/drain region 132 may be covered by the insulation liner 142, and a portion of the insulation liner 142 covering the third portion 130C of the first source/drain region 131 and a portion of the insulation liner 142 covering the third portion 130C of the second source/drain region 132 may be separated from each other by a second separation distance D2 in the second horizontal direction (Y direction). For example, the second separation distance D2 may be less than the first separation distance D1.

According to some embodiments, the width of an upper end of each of the plurality of buried insulation blocks 174 in the second horizontal direction (Y direction) may have a first length L1. According to some embodiments, the first length L1 may be equal to the second separation distance D2, and, in this case, the upper end of each of the plurality of buried insulation blocks 174 may contact (e.g., directly contact) the insulation liner 142 in the second horizontal direction (Y direction). For example, both sidewalls of the upper end of each of the plurality of buried insulation blocks 174 may face the source/drain pair 134 with the insulation liner 142 therebetween. For example, as illustrated in FIG. 2D, upper ends of opposite sidewalls of each of the plurality of buried insulation blocks 174 may directly contact outer edges of the insulation liner 142 on the third portions 130C of the first and second source/drain regions 131 and 132 within each of the source/drain pairs 134, such that an entirety of the active contact 186 may be above the buried insulation block 174 and the third portions 130C of the source/drain pair 134.

A first structure including the first source/drain region 131 and the insulation liner 142 covering the first source/drain region 131 and a second structure including the second source/drain region 132 and the insulation liner 142 covering the second source/drain region 132 may be separated from each other by the second seperation distance D2 in the second horizontal direction (Y direction). Each of the plurality of buried insulation blocks 174 may be disposed below the first vertical level LV1 between the first structure and the second structure in the second horizontal direction (Y direction) to prevent the plurality of active contacts 186 from extending below the first vertical level LV1 through the space between the first structure and the second structure. For example, the plurality of active contacts 186 may not extend to a vertical level lower than the first vertical level LV1.

According to some embodiments, the second portions 186B of the plurality of active contacts 186 may contact top surfaces of the plurality of buried insulation blocks 174 and top surfaces of the portions of the insulation liner 142 contacting the upper ends of the plurality of buried insulation blocks 174.

According to some embodiments, surfaces of the plurality of buried insulation blocks 174 other than the top surfaces of the plurality of buried insulation blocks 174 may be covered by the inter-gate insulation layer 144 and the insulation liner 142. For example, both sidewalls of each of the plurality of buried insulation blocks 174 may face the first portion 130A of each of the source/drain pairs 134 with the inter-gate insulation layer 144 and the insulation liner 142 therebetween.

According to some embodiments, the plurality of buried insulation blocks 174 may each have a tapered shape such that the width thereof in the second horizontal direction (Y direction) decreases in a direction oriented away from the top surface in the vertical direction (Z direction). For example, the horizontal width of a portion of each of the plurality of buried insulation blocks 174 relatively close to the main surface 102M of the substrate 102 may be less than the horizontal width of a portion of each of the plurality of buried insulation blocks 174 relatively far from the main surface 102M of the substrate 102.

According to some embodiments, the plurality of buried insulation blocks 174 may include, e.g., a silicon nitride film, a silicon oxide film, a SiCN film, a SiON film, a SiOCN film, or a combination thereof. According to some embodiments, the plurality of buried insulation blocks 174 may include a material that is different from materials constituting the inter-gate insulation layer 144 and the insulation liner 142.

For example, as illustrated in FIG. 2C, one active contact 186 may contact two source/drain regions 130 together. In another example, unlike that shown in FIG. 2C, one active contact 186 may contact three or more source/drain regions 130 together. In this case, the buried insulation blocks 174 may be respectively arranged between groups of the three or more source/drain regions 130.

The integrated circuit device 100 according to embodiments may include the plurality of buried insulation blocks 174 respectively arranged under the plurality of active contacts 186. The plurality of buried insulation blocks 174 may prevent the plurality of active contacts 186 from extending deep in the vertical direction (Z direction) to a vertical level lower than the third portion 130C of each of the plurality of source/drain regions 130 or covering the first portion 130A of each of the plurality of source/drain regions 130. Therefore, the plurality of active contacts 186 may contact the top surface and the sidewalls of the second portion 130B of each of the plurality of source/drain regions 130 to secure a wide contact area and suppress parasitic capacitance between the gate lines 160 adjacent to the plurality of active contacts 186. Also, the plurality of active contacts 186 may be spaced apart from one another with the contact cut insulation portions 172 therebetween in the second horizontal direction (Y direction). The plurality of active contacts 186 may be arranged in the contact holes 186H formed by using the contact cut insulation portions 172 as an etch mask, and thus, short-circuits between the plurality of active contacts 186 adjacent to one another that may occur due to down-scaling may be easily prevented.

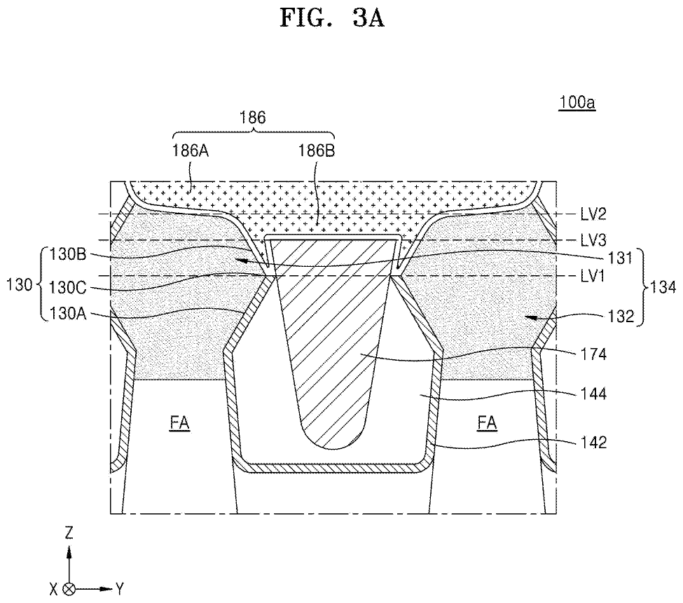

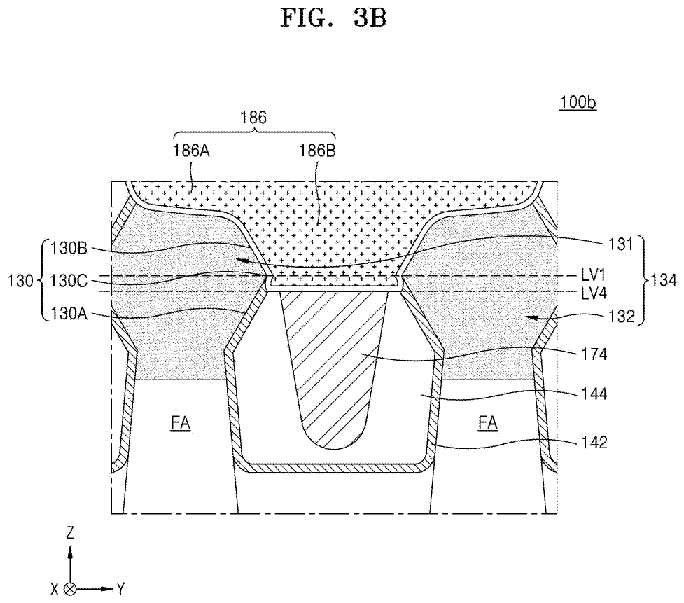

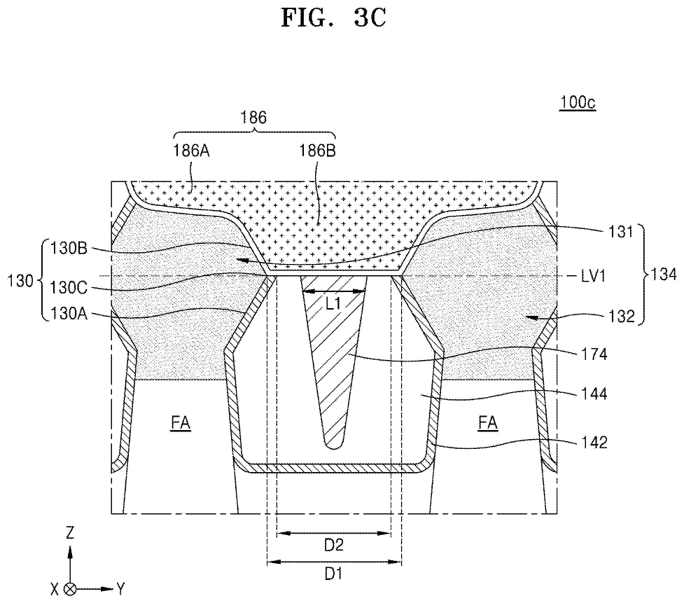

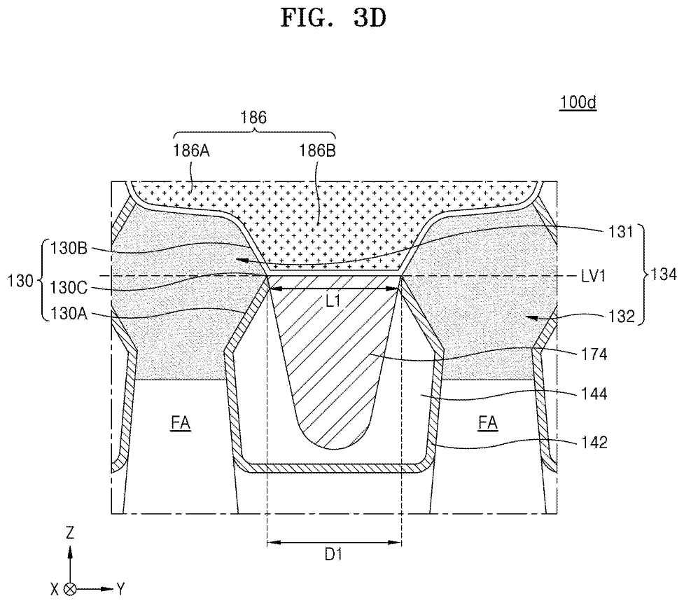

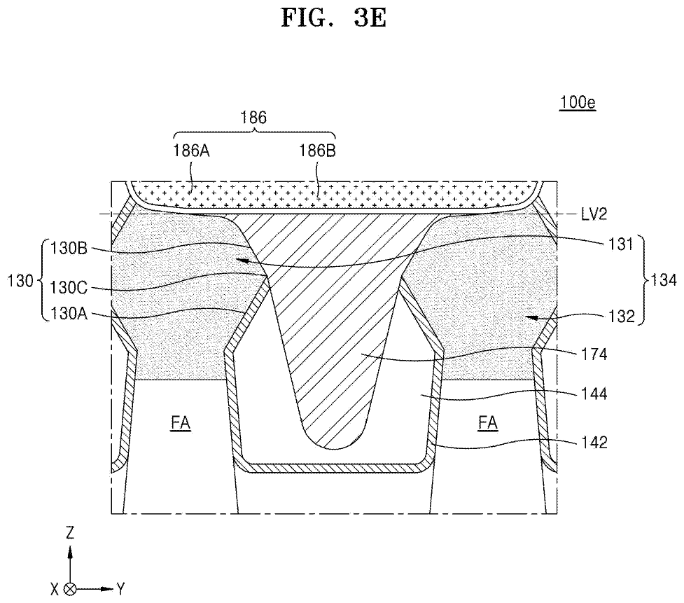

FIG. 3A is a cross-sectional view for describing an integrated circuit device 100a according to other embodiments and shows a portion corresponding to FIG. 2D. In detail, FIG. 3A is an enlarged cross-sectional view of the configuration of a portion of the integrated circuit device 100a corresponding to “EX1” of FIG. 2D. In FIG. 3A, the same reference numerals as those in FIGS. 1 and 2A to 2D denote the same members, and detailed descriptions thereof will be omitted below.

Referring to FIG. 3A, the top surfaces of the plurality of buried insulation blocks 174 of the integrated circuit device 100a may be arranged at a third vertical level LV3 higher than the first vertical level LV1. For example, each of the plurality of buried insulation blocks 174 may include an upper portion positioned at a vertical level higher than the first vertical level LV1, and the upper portion of each of the plurality of buried insulation blocks 174 may be disposed between the second portion 130B of the first source/drain region 131 and the second portion 130B of the second source/drain region 132. According to some embodiments, the second portions 186B of the plurality of active contacts 186 may cover top surfaces of the plurality of buried insulation blocks 174 and sidewalls of the upper portions of the plurality of buried insulation blocks 174. In this specification, the upper portions of the plurality of buried insulation blocks 174, that is, portions of the plurality of buried insulation blocks 174 extending above the first vertical level LV1, may be referred to as extensions of the plurality of buried insulation blocks 174.

According to some embodiments, the second portions 186B of the plurality of active contacts 186 may cover sidewalls of the source/drain pairs 134 arranged to face each other in the second horizontal direction (Y direction) and may surround the upper portions of the plurality of buried insulation blocks 174.

According to some embodiments, the upper portion of each of the plurality of buried insulation blocks 174 may face the second portion 130B of the first source/drain region 131 and the second portion 130B of the second source/drain region 132 with portions of each of the plurality of active contacts 186 therebetween in the second horizontal direction (Y direction).

For example, as illustrated in FIG. 3A, the top surfaces of the plurality of buried insulation blocks 174 may be arranged at a vertical level lower than the second vertical level LV2. In another example, the top surfaces of the plurality of buried insulation blocks 174 may be arranged at a vertical level that is the same as or higher than the second vertical level LV2.

FIG. 3B is a cross-sectional view for describing an integrated circuit device 100b according to other embodiments and shows a portion corresponding to FIG. 2D. In detail, FIG. 3B is an enlarged cross-sectional view of the configuration of a portion of the integrated circuit device 100b corresponding to “EX1” of FIG. 2D. In FIG. 3B, the same reference numerals as those in FIGS. 1 and 2A to 2D denote the same members, and detailed descriptions thereof will be omitted below.

Referring to FIG. 3B, the top surfaces of the plurality of buried insulation blocks 174 of the integrated circuit device 100b may be arranged at a fourth vertical level LV4 lower than the first vertical level LV1. According to some embodiments, the second portion 186B of each of the plurality of active contacts 186 may contact the top surface of each of the plurality of buried insulation blocks 174 at the fourth vertical level LV4.

According to some embodiments, the second portion 186B of each of the plurality of active contacts 186 may include a portion contacting each of the plurality of buried insulation blocks 174, a portion contacting the insulation liner 142, a portion contacting the inter-gate insulation layer 144, and a portion contacting the second portion 130B of each of the plurality of source/drain pairs 134. According to some embodiments, the plurality of active contacts 186 may face first portions 130A of the plurality of source/drain pairs 134 with the insulation liner 142 therebetween in the second horizontal direction (Y direction).

According to some embodiments, the second portion 186B of each of the plurality of active contacts 186 may contact the sidewall of the second portion 130B of the plurality of source/drain pairs 134 but may not contact the sidewall of the first portion 130A of the plurality of source/drain pairs 134.

For example, as illustrated in FIG. 3B, the bottom surfaces of the second portions 186B of the plurality of active contacts 186 are relatively flat and cover the top surfaces of the plurality of buried insulation blocks 174 and the top surface of the inter-gate insulation layer 144 that are arranged on the same plane. For example, a portion of the second portion 186B of each of the plurality of active contacts 186 may penetrate through a portion of the inter-gate insulation layer 144 and extend to a vertical level lower than the fourth vertical level LV4. In this case, portions of both sidewalls of the plurality of buried insulation blocks 174 in the second horizontal direction (Y direction) may be covered by the second portions 186B of the plurality of active contacts 186.

FIG. 3C is a cross-sectional view for describing an integrated circuit device 100c according to other embodiments and shows a portion corresponding to FIG. 2D. In detail, FIG. 3C is an enlarged cross-sectional view of the configuration of a portion of the integrated circuit device 100c corresponding to “EX1” of FIG. 2D. In FIG. 3C, the same reference numerals as those in FIGS. 1 and 2A to 2D denote the same members, and detailed descriptions thereof will be omitted below.

Referring to FIG. 3C, the first length L1, which is the width of the top surface of each of the plurality of buried insulation blocks 174 in the second horizontal direction (Y direction), may be less than the second separation distance D2. According to some embodiments, the second portion 186B of each of the plurality of active contacts 186 may include a portion contacting each of the plurality of buried insulation blocks 174, a portion contacting the insulation liner 142, a portion contacting the inter-gate insulation layer 144, and a portion contacting the second portion 130B of each of the plurality of source/drain pairs 134. According to some embodiments, both sidewalls of the plurality of buried insulation blocks 174 in the second horizontal direction (Y direction) may face the insulation liner 142 with the inter-gate insulation layer 144 therebetween.

For example, as illustrated in FIG. 3C, the bottom surfaces of the second portions 186B of the plurality of active contacts 186 are relatively flat and cover the top surfaces of the plurality of buried insulation blocks 174, the top surface of the inter-gate insulation layer 144, and the top surface of the insulation liner 142 that are arranged on the same plane. For example, the second portion 186B of each of the plurality of active contacts 186 may penetrate through the inter-gate insulation layer 144 and extend to a vertical level lower than the first vertical level LV1. In this case, portions of both sidewalls of the plurality of buried insulation blocks 174 in the second horizontal direction (Y direction) may be covered by the second portions 186B of the plurality of active contacts 186.

FIG. 3D is a cross-sectional view for describing an integrated circuit device 100d according to other embodiments and shows a portion corresponding to FIG. 2D. In detail, FIG. 3D is an enlarged cross-sectional view of the configuration of a portion of the integrated circuit device 100d corresponding to “EX1” of FIG. 2D. In FIG. 3D, the same reference numerals as those in FIGS. 1 and 2A to 2D denote the same members, and detailed descriptions thereof will be omitted below.

Referring to FIG. 3D, the first length L1, which is the width of the top surface of each of the plurality of buried insulation blocks 174 in the second horizontal direction (Y direction), may be equal to the first separation distance D1.

According to some embodiments, both sides of the upper portion of each of the plurality of buried insulation blocks 174 in the second horizontal direction (Y direction) may contact the third portion 130C of the source/drain pair 134 and the insulation liner 142. For example, both ends of the upper portion of each of the plurality of buried insulation blocks 174 may directly contact the third portion 130C of the source/drain pair 134, and the second portion 186B of each of the plurality of active contacts 186 may contact the top surface of each of the plurality of buried insulation blocks 174 and may not contact the insulation liner 142.

FIG. 3E is a cross-sectional view for describing an integrated circuit device 100e according to other embodiments and shows a portion corresponding to FIG. 2D. In detail, FIG. 3E is an enlarged cross-sectional view of the configuration of a portion of the integrated circuit device 100e corresponding to “EX1” of FIG. 2D. In FIG. 3E, the same reference numerals as those in FIGS. 1 and 2A to 2D denote the same members, and detailed descriptions thereof will be omitted below.

Referring to FIG. 3E, the top surfaces of the plurality of buried insulation blocks 174 may be arranged at the second vertical level LV2. According to some embodiments, the bottom surfaces of the first portions 186A of the plurality of active contacts 186 may be arranged at the same vertical level as the bottom surfaces of the second portions 186B of the plurality of active contacts 186. According to some embodiments, the first portion 186A of each of the plurality of active contacts 186 may contact the source/drain pair 134 at the second vertical level LV2, and the second portions 186B of the plurality of active contacts 186 may contact the plurality of buried insulation blocks 174 at the second vertical level LV2, respectively. In this case, unlike the integrated circuit device 100 shown in FIGS. 1 and 2A to 2D, the second portion 186B of the integrated circuit device 100e may not include a portion protruding from the bottom surface of the first portion 186A in a direction toward a substrate.

According to some embodiments, each of the plurality of buried insulation blocks 174 may contact facing sidewalls of the second portion 130B of the source/drain pair 134. According to some embodiments, each of the plurality of buried insulation blocks 174 may contact the third portion 130C of the source/drain pair 134.

According to some embodiments, a space between the source/drain pairs 134 may be filled with the buried insulation block 174, the inter-gate insulation layer 144, and the insulation liner 142. For example, the plurality of active contacts 186 may not include portions arranged in the first source/drain region 131 and the second source/drain region 132.

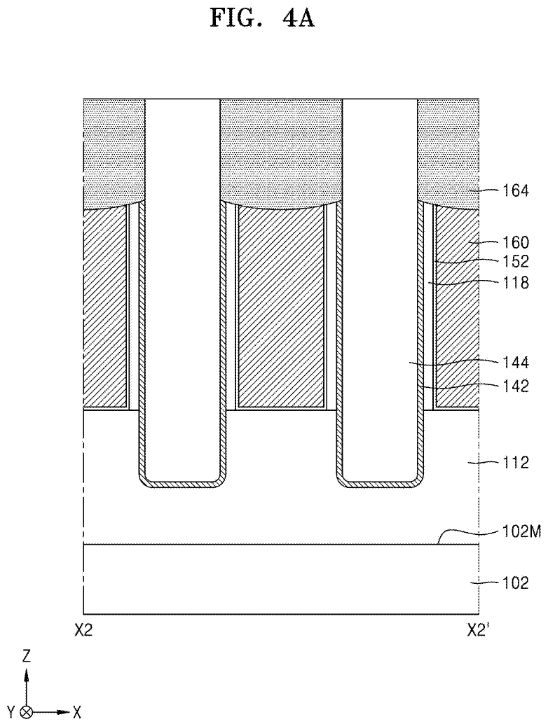

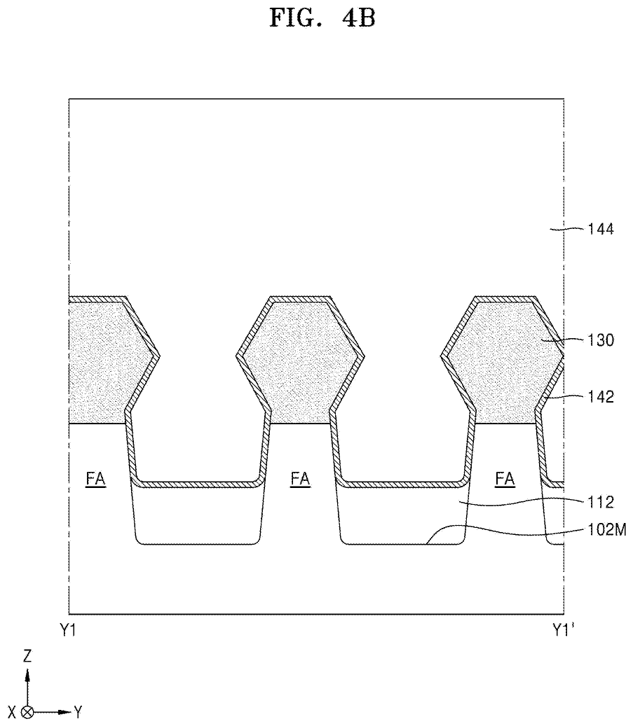

FIGS. 4A to 8B are cross-sectional views of stages in a method of manufacturing an integrated circuit device according to embodiments, wherein FIGS. 4A, 5A, 6A, 7A, and 8A are cross-sectional views of some components corresponding to the cross-section along line X2-X2′ of FIG. 1, and FIGS. 4B, 5B, 6B, 7B, and 8B are cross-sectional views of some components corresponding to the cross-section along line Y1-Y1′ of FIG. 1.

Referring to FIGS. 4A and 4B together, a plurality of nano-sheet stacks NSS (refer to FIG. 2A) and the plurality of source/drain regions 130 may be formed on the substrate 102 having the plurality of fin-type active regions FA defined by the device isolation layer 112. In this process, the outer insulation spacer 118 may be formed on the plurality of nano-sheet stacks NSS and the device isolation layer 112.

Thereafter, the insulation liner 142 covering the plurality of source/drain regions 130, the device isolation layer 112, and sidewalls of the upper portions of the plurality of fin-type active regions FA may be formed, and the inter-gate insulation layer 144 may be formed on the insulation liner 142.

Thereafter, after the inner insulation spacer 154 (FIG. 2A) is formed between first to fourth nano-sheets N1, N2, N3, and N4 constituting the plurality of nano-sheet stacks NSS, the gate dielectric layer 152 and the plurality of gate lines 160 may be formed in a space defined by the plurality of nano-sheet stacks NSS and the outer insulation spacer 118. Thereafter, after recessing portions of the plurality of gate lines 160, the gate dielectric layer 152, the outer insulation spacer 118, and the insulation liner 142, the capping insulation layer 164 covering top surfaces thereof may be formed.

According to some other embodiments, the insulation liner 142 may not be recessed, and the capping insulation layer 164 may cover the top surfaces of the plurality of gate lines 160, the top surface of the gate dielectric layer 152, and the top surface of the outer insulation spacer 118 but may not cover the top surface of insulation liner 142.

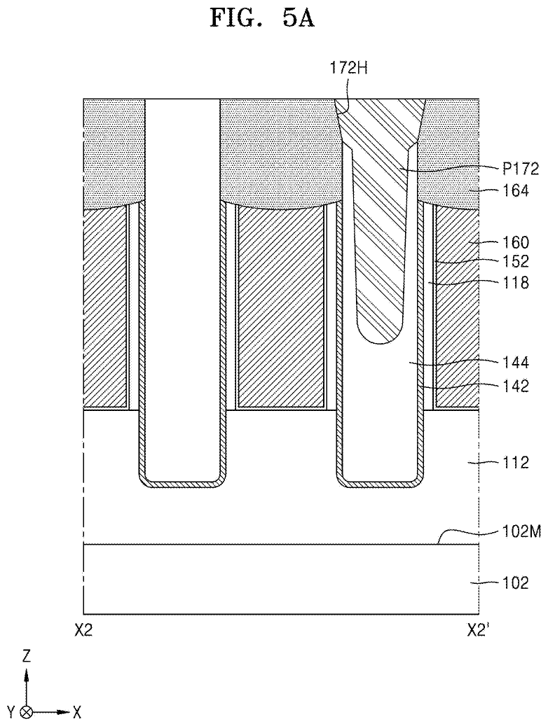

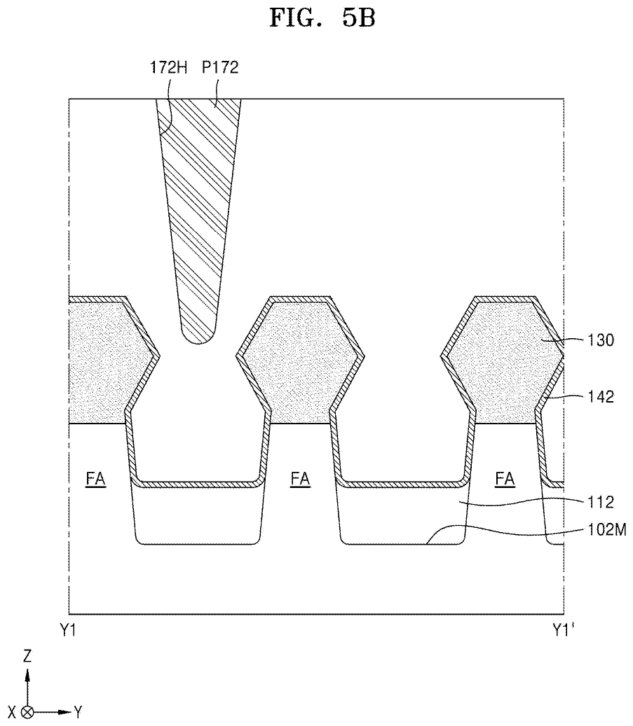

Referring to FIGS. 5A and 5B, in the resultant structure of FIGS. 4A and 4B, a first mask exposing a portion of the top surface of the inter-gate insulation layer 144 may be formed, and then a portion of the inter-gate insulation layer 144 may be removed to form the contact cut holes 172H. In this process, the capping insulation layer 164 may have an etching selectivity with respect to the inter-gate insulation layer 144 and may be used as an etching mask together with the first mask. A portion of the capping insulation layer 164 adjacent to the inter-gate insulation layer 144 may be removed together. Thereafter, a preliminary contact cut insulation portion P172 may be formed by filling the contact cut holes 172H with an insulation material. According to some embodiments, the preliminary contact cut insulation portion P172 may have an etch selectivity with respect to the inter-gate insulation layer 144. For example, as shown in FIG. 5A, the preliminary contact cut insulation portion P172 may include a portion of which the width in the second horizontal direction (Y direction) rapidly decreases at the interface between the capping insulation layer 164 and the inter-gate insulation layer 144.

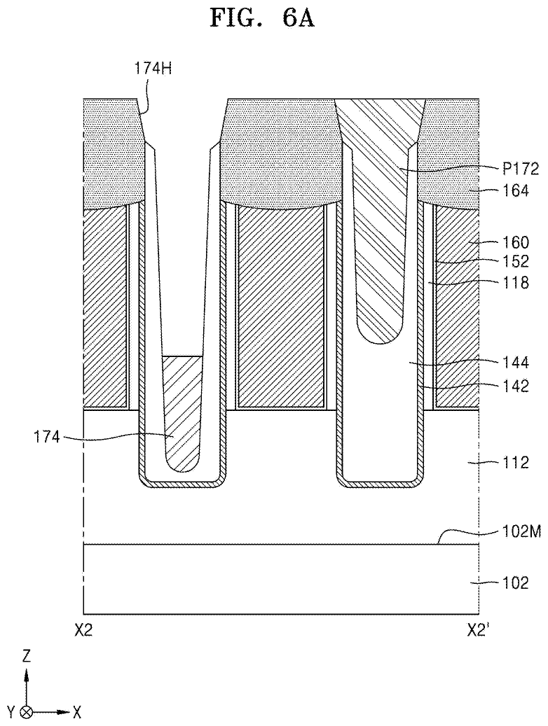

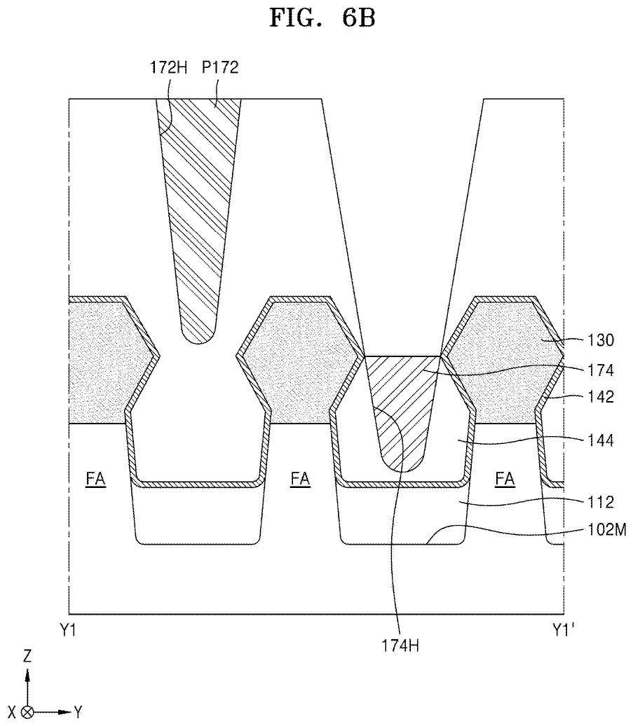

Referring to FIGS. 6A and 6B, in the resultant structure of FIGS. 5A and 5B, a second mask exposing a portion of the top surface of the inter-gate insulation layer 144 may be formed, and then a portion of the inter-gate insulation layer 144 may be removed to form a block hole 174H.

In this process, the capping insulation layer 164 may be used as an etching mask together with the second mask, and a portion of the capping insulation layer 164 may be removed together. Thereafter, an insulation block may be formed by filling the block hole 174H with an insulation material, and then an upper portion of the insulation block may be removed to form the buried insulation block 174. Therefore, a space limited by the buried insulation block 174, the inter-gate insulation layer 144, and the plurality of source/drain regions 130 may be formed on the buried insulation block 174. The insulation block may have an etch selectivity with respect to the inter-gate insulation layer 144. For example, the buried insulation block 174 may be a lower portion of the insulation block remaining without being removed.

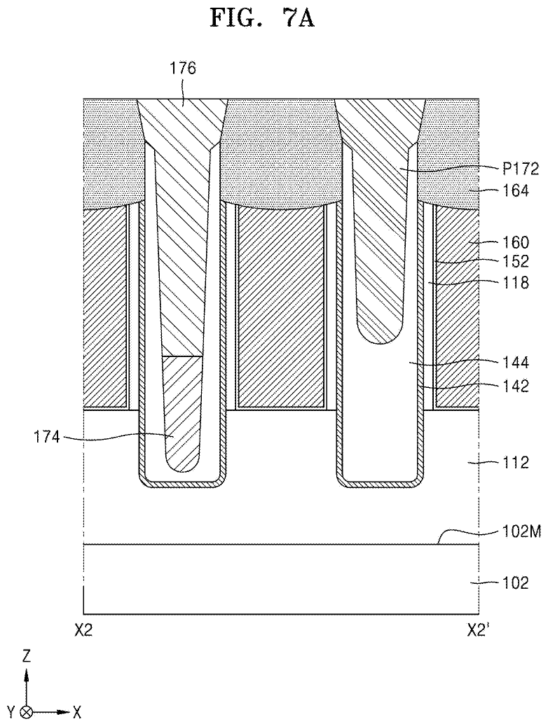

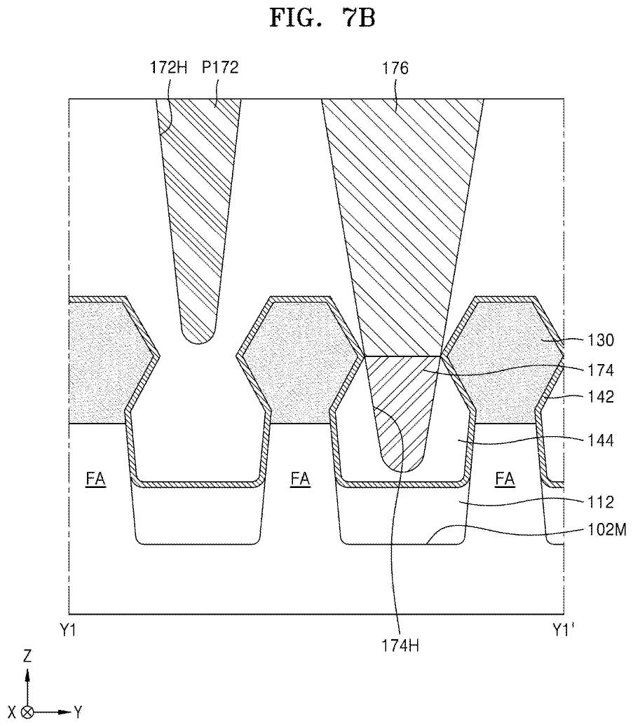

Referring to FIGS. 7A and 7B, in the result structure of FIGS. 6A and 6B, a sacrificial insulation block 176 filling the empty portion of the block hole 174H may be formed on the buried insulation block 174. According to some embodiments, the sacrificial insulation block 176 may include, e.g., a silicon nitride film, a silicon oxide film, a SiCN film, a SiON film, a SiOCN film, or a combination thereof. The sacrificial insulation block 176 may have an etch selectivity with respect to the buried insulation block 174. The sacrificial insulation block 176 may fill the empty portion of the block hole 174H to maintain the top surface of the integrated circuit device 100 flat in the process of forming the integrated circuit device 100, thereby suppressing process variation.

According to some other embodiments, a process of forming the sacrificial insulation block 176 may be omitted.

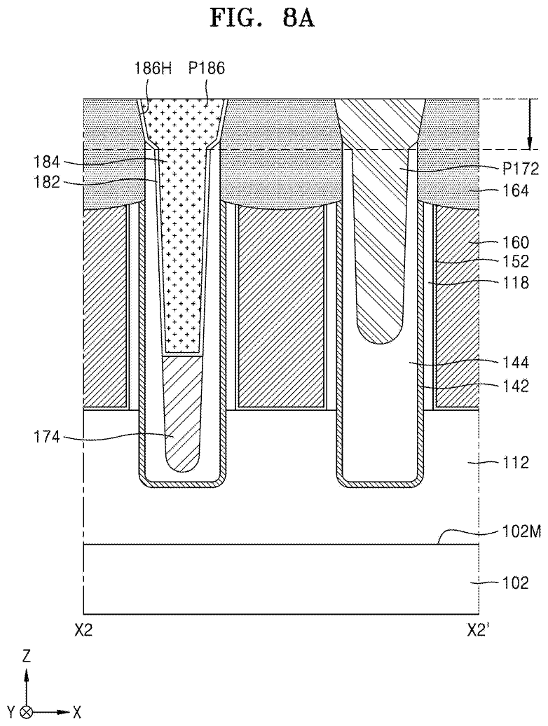

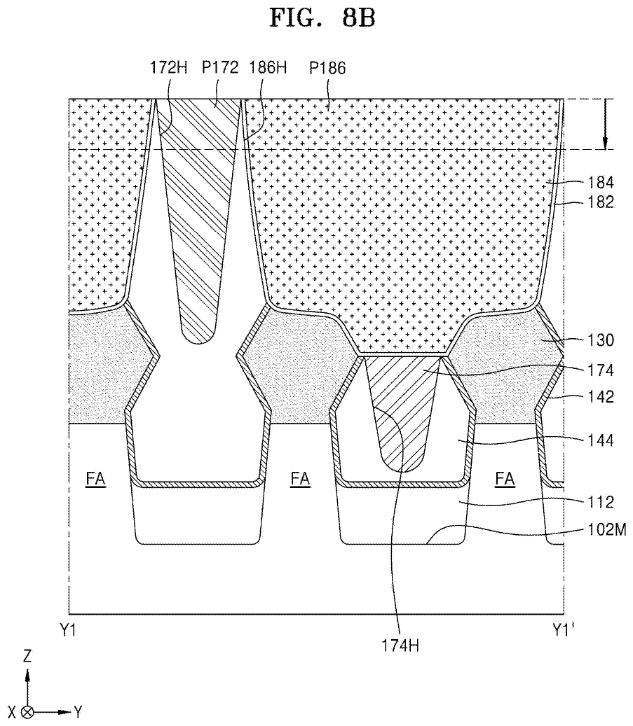

Referring to FIGS. 8A and 8B, in the resultant structure of FIGS. 7A and 7B, by using the capping insulation layer 164 and the preliminary contact cut insulation portions P172 as etching masks, the sacrificial insulation block 176, a portion of the inter-gate insulation layer 144, and a portion of the insulation liner 142 may be removed, thereby forming the contact holes 186H. According to some embodiments, portions of the plurality of source/drain regions 130 may be removed together in the process of forming the contact holes 186H.

Thereafter, the conductive barrier 182 may be formed to cover the bottom surface and the inner wall of the contact hole 186H. A metal silicide having a certain thickness in a direction oriented toward the plurality of source/drain regions 130 may be formed at the interface between the conductive barrier 182 and the plurality of source/drain regions 130 through an annealing process through the conductive barrier 182. Thereafter, the conductive plug 184 filling the empty space of the contact hole 186H may be formed on the conductive barrier 182, thereby forming a preliminary active contact P186. For example, as shown in FIG. 8A, the preliminary active contact P186 may include a portion of which the width in the second horizontal direction (Y direction) rapidly decreases at the interface between the capping insulation layer 164 and the inter-gate insulation layer 144.

Referring to FIGS. 8A and 8B together with FIGS. 2B and 2C, in the resultant structure of FIGS. 8A and 8B, the preliminary active contact P186, the plurality of preliminary contact cut insulation portions P172, the inter-gate insulation layer 144, and the capping insulation layer 164 may be planarized. According to some embodiments, the portion of the preliminary active contact P186 having the width in the second horizontal direction (Y direction) abruptly changing at the interface between the capping insulation layer 164 and the inter-gate insulation layer 144 may be removed to form the plurality of active contacts 186, and portions of the plurality of preliminary contact cut insulation portions P172 having the width in the second horizontal direction (Y direction) abruptly changing at the interface between the capping insulation layer 164 and the inter-gate insulation layer 144 may be removed to form the plurality of contact cut insulation portions 172.

In an integrated circuit device according to a comparative example, an unwanted short circuit may occur between conductive regions (e.g., active contacts) adjacent to each other. In the integrated circuit device according to the comparative example, as the distance between the plurality of gate lines 160 is reduced, it may be more difficult to form a trench by removing the inter-gate insulation layer 144 between the plurality of gate lines 160, fill the trench, and form a contact cut. According to a method of manufacturing the integrated circuit device 100 according to embodiments, the contact cut insulation portions 172 may be formed before the active contacts 186, and the capping insulation layer 164 and the contact cut insulation portions 172 may be used as etching masks to form the plurality of active contacts 186. Therefore, even when the intervals between the plurality of gate lines 160 have a narrow pitch, stable separation and insulation between the plurality of adjacent active contacts 186 may be possible.

By way of summation and review, embodiments provide an integrated circuit device having a structure capable of preventing unwanted parasitic capacitance and/or short circuits between adjacent conductive regions due to downscaling and improving reliability. Embodiments provide a method of manufacturing an integrated circuit device having a structure capable of preventing unwanted parasitic capacitance and/or short circuits between adjacent conductive regions due to downscaling and improving reliability.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. An integrated circuit device, comprising:
a substrate having a main surface and fin-type active regions protruding in a vertical direction from the main surface, the fin-type active regions extending lengthwise in a first horizontal direction;
gate lines extending parallel to one another in a second horizontal direction perpendicular to the first horizontal direction and crossing the fin-type active regions on the substrate;
source/drain regions arranged on the fin-type active regions between the gate lines;
an inter-gate insulation layer covering the source/drain regions between the gate lines;
active contacts arranged on the source/drain regions and in contact with the source/drain regions; and
a buried insulation block between a first one of the source/drain regions and a second one of the source/drain regions that is adjacent to the first one of the source/drain regions in the second horizontal direction, the buried insulation block penetrating through at least a portion of the inter-gate insulation layer and having a top surface in contact with a first active contact of the active contacts.

2. The integrated circuit device as claimed in claim 1, further comprising contact cut insulation portions extending in the vertical direction between the gate lines on the substrate and arranged between the active contacts in the second horizontal direction, respectively.

3. The integrated circuit device as claimed in claim 2, wherein a width of each of the contact cut insulation portions in the second horizontal direction decreases in a direction oriented toward the main surface of the substrate.

4. The integrated circuit device as claimed in claim 1, wherein:
each of the source/drain regions includes:
a first portion having a positive profile extending such that a width of the first portion in the second horizontal direction increases as a distance from the main surface of the substrate increases,
a second portion extending in the vertical direction from the first portion and having a negative profile such that a width of the second portion in the second horizontal direction decreases as the distance from the main surface of the substrate increases, and
a third portion having a maximum width in the second horizontal direction between the first portion and the second portion, and
the buried insulation block is between the first portion of the first one of the source/drain regions and the first portion of the second one of the source/drain regions.

5. The integrated circuit device as claimed in claim 4, wherein:
the third portion of the first one of the source/drain regions, the third portion of the second one of the source/drain regions, and a top surface of the buried insulation block are arranged at a same vertical level, and
both sidewalls of the buried insulation block in the second horizontal direction contact the third portion of the first one of the source/drain regions and the third portion of the second one of the source/drain regions, respectively.

6. The integrated circuit device as claimed in claim 4, further comprising an insulation liner covering the source/drain regions and disposed between the source/drain regions and the inter-gate insulation layer,
wherein:
the active contacts penetrate through the insulation liner and contact the source/drain regions,
the third portion of the first one of the source/drain regions, the third portion of the second one of the source/drain regions, and the top surface of the buried insulation block are arranged at a same vertical level, and
both sidewalls of the buried insulation block in the second horizontal direction are respectively separated from the third portion of the first one of the source/drain regions and the third portion of the second one of the source/drain regions with the insulation liner therebetween.

7. The integrated circuit device as claimed in claim 4, wherein:
the top surface of the buried insulation block is at a vertical level higher than that of the third portion of the first one of the source/drain regions and the third portion of the second one of the source/drain regions, and
both sidewalls of the buried insulation block in the second horizontal direction include portions contacting the second portion of the first one of the source/drain regions and the second portion of the second one of the source/drain regions.

8. The integrated circuit device as claimed in claim 4, wherein:
the buried insulation block includes an upper portion at a vertical level higher than that of the third portion of the first one of the source/drain regions and the third portion of the second one of the source/drain regions, and
the upper portion of the buried insulation block is surrounded by the first active contact.

9. The integrated circuit device as claimed in claim 4, wherein:
the top surface of the buried insulation block is at a vertical level lower than that of the third portion of the first one of the source/drain regions and the third portion of the second one of the source/drain regions,
the first active contact covers the second portion of the first one of the source/drain regions and the second portion of the second one of the source/drain regions, and
the first portion of the first one of the source/drain regions and the first portion of the second one of the source/drain regions are not covered.

10. The integrated circuit device as claimed in claim 1, wherein the first active contact covers a top surface of the first one of the source/drain regions, a top surface of the second one of the source/drain regions, and the top surface of the buried insulation block together.

11. An integrated circuit device, comprising:
a substrate having a main surface and fin-type active regions protruding in a vertical direction from the main surface, the fin-type active regions extending lengthwise in a first horizontal direction;
gate lines extending parallel to one another in a second horizontal direction perpendicular to the first horizontal direction and crossing the fin-type active regions on the substrate;
source/drain regions arranged on the fin-type active regions between the gate lines, each of the source/drain regions including a lower portion having a width in the second horizontal direction increasing as a distance from the main surface of the substrate in the vertical direction increases and an upper portion having a width in the second horizontal direction decreasing as a distance from the main surface of the substrate in the vertical direction increases;
an inter-gate insulation layer covering the source/drain regions between the gate lines;
a buried insulation block between a first source/drain region of the source/drain regions and a second source/drain region of the source/drain regions that is adjacent to the first source/drain region in the second horizontal direction, the buried insulation block penetrating through at least a portion of the inter-gate insulation layer and extending in the vertical direction; and
an active contact including a first portion in contact with a top surface of the first source/drain region and a top surface of the second source/drain region, and a second portion protruding from the first portion toward the substrate in the vertical direction and contacting a top surface of the buried insulation block.

12. The integrated circuit device as claimed in claim 11, wherein the second portion of the active contact covers sidewalls of the upper portion of the first source/drain region and sidewalls of the upper portion of the second source/drain region, which face each other.

13. The integrated circuit device as claimed in claim 11, wherein the buried insulation block includes an extension between the upper portion of the first source/drain region and the upper portion of the second source/drain region, the extension of the buried insulation block being surrounded by the second portion of the active contact.

14. The integrated circuit device as claimed in claim 11, wherein opposite sidewalls of the buried insulation block in the second horizontal direction contact the first source/drain region and the second source/drain region, respectively.

15. The integrated circuit device as claimed in claim 11, wherein a width of the buried insulation block in the second horizontal direction decreases in a direction oriented toward the main surface of the substrate.

16. An integrated circuit device, comprising:
a substrate having fin-type active regions extending lengthwise in a first horizontal direction;
gate lines extending parallel to one another in a second horizontal direction perpendicular to the first horizontal direction and crossing the fin-type active regions on the substrate;
source/drain pairs arranged on the fin-type active regions between the gate lines, each including two source/drain regions adjacent to each other in the second horizontal direction;
an insulation liner covering the source/drain pairs between the gate lines;
an inter-gate insulation layer on the insulation liner;
buried insulation blocks between the source/drain pairs;
active contacts on the source/drain pairs and in contact with the buried insulation blocks, respectively; and
contact cut insulation portions extending in a vertical direction between the gate lines on the substrate and between the active contacts in the second horizontal direction, respectively.

17. The integrated circuit device as claimed in claim 16, wherein the contact cut insulation portions are spaced apart from the active contacts in the second horizontal direction with the inter-gate insulation layer therebetween.

18. The integrated circuit device as claimed in claim 16, wherein the buried insulation blocks include a material different from a material constituting the inter-gate insulation layer.

19. The integrated circuit device as claimed in claim 16, wherein top surfaces of the buried insulation blocks are closer to the substrate than top surfaces of the source/drain pairs.

20. The integrated circuit device as claimed in claim 16, wherein at least one of the buried insulation blocks covers sidewalls of upper portions of the source/drain pairs.
